(19) United States
(12) Patent Application Publication
(10) Pub. No.: US 2026/0271591 A1
(43) Pub. Date: Sep. 10, 2026

(54) DISPLAY DEVICE AND ELECTRONIC DEVICE INCLUDING THE SAME

(71) Applicant: Samsung Display Co., LTD., Yongin-si (KR)

(72) Inventors: Hwi Seong KIM, Yongin-si (KR); Dong Hoo KIM, Yongin-si (KR); Min Woo KIM, Yongin-si (KR); Ji Hun Park, Yongin-si (KR); Jae Man LEE, Yongin-si (KR); Sang Jin CHOI, Yongin-si (KR); Soo Jeong CHOI, Yongin-si (KR); Seung Cheol HA, Yongin-si (KR); Sun Young KIM, Yongin-si (KR); Maeng Ha LEE, Yongin-si (KR)

(21) Appl. No.: 19/555,127

(22) Filed: Mar. 3, 2026

(30) Foreign Application Priority Data
Mar. 6, 2025 (KR) 10-2025-0028651
Nov. 11, 2025 (KR) 10-2025-0168943

(51) Int. Cl. H10K 59/80; H10K 59/121

(52) U.S. Cl. CPC H10K 59/873; H10K 59/1213

(57) ABSTRACT

A display device includes a first substrate, a plurality of light-emitting elements arranged in a display area on the first substrate and outputting light, a plurality of first area dams arranged in a non-display area next (adjacent) to the display area and spaced apart from one another, a sealing member disposed in a space between the plurality of first area dams and over the plurality of first area dams and a filling member disposed over the plurality of light-emitting elements and surrounded by the sealing member.

This application claims priority to Korean Patent Application No. 10-2025-0028651, filed on Mar. 06, 2025, and Korean Patent Application No. 10-2025-0168943, filed on Nov. 11, 2025, and all the benefits accruing therefrom under 35 U.S.C. §119, the contents of which in their entirety are herein incorporated by reference.

### BACKGROUND

### 1. Field

The disclosure relates to a display device and an electronic device including the same.

### 2. Description of the Related Art

As the information-oriented society evolves, various demands for display devices are ever increasing. Display devices may be flat panel display devices such as a liquid-crystal display device, a field emission display device, and a light-emitting display device. Light-emitting display devices may include an organic light-emitting display device including an organic light-emitting element, an inorganic light-emitting display device including an inorganic light-emitting element such as an inorganic semiconductor, and a micro-light-emitting display device including an ultra-small light-emitting element.

No separate light source such as a backlight unit is desired in an organic light-emitting display device including organic light-emitting elements, and thus it consumes less power and may be made relatively light and relatively thin, as well as exhibiting high-quality characteristics such as relatively wide viewing angle, relatively high luminance and contrast, and relatively fast response speed. Accordingly, an organic light-emitting display device is attracting attention as the next generation display device.

The organic materials and electrodes in organic light-emitting display devices are sensitive to oxygen and moisture, which may affect the lifespan and emission characteristics of organic light-emitting elements. Therefore, an encapsulation process is desired to block oxygen and moisture. When encapsulating the device with a substrate, bubbles may be generated during a process of applying a filling member between the substrate and a panel. Such bubbles may be seen when the display is viewed from the front.

### SUMMARY

Features of the disclosure provide a display device that may prevent bubbles from being generated during a process of applying a filling member between a first substrate and a second substrate when the device is encapsulated with a substrate.

It should be noted that features of the disclosure are not limited to the above-mentioned object; and other features of the disclosure will be apparent to those skilled in the art from the following descriptions.

In an embodiment of the disclosure, there is provided a display device including a first substrate, a plurality of light-emitting elements arranged in a display area on the first substrate and outputting light, a plurality of first area dams arranged in a non-display area next (adjacent) to the display area and spaced apart from one another, a sealing member disposed in a space between the plurality of first area dams and over the plurality of first area dams and a filling member disposed over the plurality of light-emitting elements and surrounded by the sealing member.

In an embodiment, a display device may further include a second substrate disposed on the filling member and the sealing member.

In an embodiment, the first area dams may be spaced apart from one another in a first direction, and where a width of the sealing member in a second direction perpendicular to the first direction may be larger than a width of the first area dams in the second direction.

In an embodiment, a display device may further include an encapsulation layer disposed between the plurality of light-emitting elements and the filling member, where the encapsulation layer includes a first inorganic encapsulation layer disposed over the plurality of light-emitting elements, an organic encapsulation layer disposed on the first inorganic encapsulation layer and a second inorganic encapsulation layer disposed on the organic encapsulation layer.

In an embodiment, a display device may further include a plurality of second area dams arranged between the plurality of first area dams and the display area in the non-display area to prevent overflow of the organic encapsulation layer.

In an embodiment, the first inorganic encapsulation layer and the second inorganic encapsulation layer may overlap with the plurality of first area dams in a thickness direction of the first substrate.

In an embodiment, the plurality of second area dams may further include a first dam and a second dam placed between the first sub-dam and the plurality of first area dams.

In an embodiment, a height of the first dam may be smaller than that of the first area dam, and where a height of the second dam may be equal to that of the first area dam.

In an embodiment, a distance between the first dam and the second dam may be smaller than a distance between the second dam and one of the first area dams that is closest to the second dam.

In an embodiment, a display device may further include an active layer disposed on the first substrate, a gate insulator disposed on the active layer, a first gate metal layer disposed on the gate insulator, a first inter-dielectric layer disposed on the first gate electrode, a second gate metal layer disposed on the first inter-dielectric layer, a second inter-dielectric layer disposed on the second gate metal layer, a first data metal layer disposed on the second inter-dielectric layer, a first planarization layer disposed on the first data metal layer, a second data metal layer disposed on the first planarization layer and a second planarization layer disposed on the second data metal layer.

In an embodiment, the plurality of first area dams may overlap with a first metal pattern including a same material as that of the second gate metal layer.

In an embodiment, the first area dams may contact the second inter-dielectric layer.

In an embodiment, the first area dams may contact the first inter-dielectric layer.

In an embodiment, each of the plurality of first area dams may include a first sub-dam including a same material as that of the first planarization layer and a second sub-dam including a same material as that of the second planarization layer.

In an embodiment, a display device may further include a first electrode of each of the light-emitting elements disposed on the second planarization layer, an emissive layer of each of the light-emitting elements disposed on the first electrode, a pixel-defining layer disposed on at least a part of the first electrode, a second electrode of each of the light-emitting elements disposed on the first electrode and the pixel-defining layer and a spacer disposed on the pixel-defining layer.

In an embodiment, each of the first area dams may further include a third sub-dam including a same material as that of the pixel-defining layer and a fourth sub-dam including a same material as that of the spacer.

In an embodiment, the first sub-dam may include a first sub-dam including the same material as that of the second planarization layer, a second sub-dam including the same material as that of the pixel-defining layer; and a third sub-dam including the same material as that of the spacer.

In an embodiment, the second sub-dam may include a first sub-dam including the same material as that of the first planarization layer and the first sub-dam of each of the first area dams, a second sub- dam including the same material as that of the second planarization layer and the second sub-dam of each of the first area dams, a third sub-dam including the same material as that of the pixel-defining layer and the third sub-dam of each of the first area dams and a fourth sub-dam including the same material as that of the spacer and the fourth sub-dam of each of the first area dams.

In an embodiment of the disclosure, there is an electronic device including a display module for displaying an image and a processor for transmitting an image data signal to the display module, where the display module includes a first substrate, a plurality of light-emitting elements arranged in a display area on the first substrate and outputting light, a plurality of first area dams arranged in a non-display area next (adjacent) to the display area and spaced apart from one another, a sealing member disposed in a space between the plurality of first area dams and over the plurality of first area dams and a filling member disposed over the plurality of light-emitting elements and surrounded by the sealing member.

In an embodiment, the first area dams may be spaced apart from one another in a first direction, where a width of the sealing member in a second direction perpendicular to the first direction may be larger than a width of the first area dams in the second direction.

By embodiments of the disclosure, there are gaps between a plurality of dams overlapping with a sealing member in a display device, and accordingly bubbles may be released through the gaps, so that it is possible to prevent the bubbles generated during a process of applying a filling member between a first substrate and a second substrate.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view of an embodiment of a display device of the disclosure.

FIG. 2 is a view showing a layout of an embodiment of the display panel according to the disclosure.

FIG. 3 is a circuit diagram showing an embodiment of a sub-pixel of a display panel.

FIG. 4 is a view showing a layout of an embodiment of the display area of FIG. 2.

FIG. 5 is a view showing a layout of an embodiment of area A1 of FIG. 2.

FIG. 6 is a view showing how bubbles are released when a filling material fills between the first substrate and the second substrate in area A1 of FIG. 2.

FIG. 7 is a cross-sectional view showing an embodiment of the display panel taken along line I1 – I1' of FIG. 4.

FIG. 8 is a cross-sectional view showing an embodiment of the display panel taken along line I2 – I2' of FIG. 5.

FIG. 9 is a cross-sectional view showing an embodiment of the display panel taken along line I3 – I3' of FIG. 5.

FIG. 10 is a cross-sectional view showing an embodiment of the display panel taken along line I4 – I4' of FIG. 5.

FIG. 11 is a cross-sectional view showing an embodiment of the display panel taken along line I5 – I5' of FIG. 5.

FIG. 12 is a cross-sectional view showing an embodiment of the display panel, taken along line I6 – I6' of FIG. 5.

FIG. 13 is a cross-sectional view showing another embodiment of the display panel, taken along line I4 – I4' of FIG. 5.

FIG. 14 is a cross-sectional view showing another embodiment of the display panel, taken along line I5 - I5' of FIG. 5.

FIG. 15 is a block diagram of an embodiment of an electronic device of the disclosure.

FIG. 16 is a view showing electronic devices according to a variety of embodiments of the disclosure.

### DETAILED DESCRIPTION

The disclosure will now be described more fully hereinafter with reference to the accompanying drawings, in which various embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art. The same reference numbers indicate the same components throughout the specification. In the attached drawing figures, the thickness of layers and regions is exaggerated for clarity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being related to another element such as being "on" another layer or substrate, it may be directly on the other layer or substrate, or intervening layers may also be present. In contrast, when an element is referred to as being related to another element such as being "directly on" another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” “At least one of A and B” or “at least one selected from A and B” means “A and/or B.” As used herein, the term “and/or” includes any and all combinations of one or more of the associated listed items. Within the drawing figures and the text of the disclosure, a reference number indicating a singular form of an element may also be used to reference a plurality of the element.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, when the device in one of the figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, when the device in one of the drawing figures is turned over, elements described as “below” or “beneath” other elements would then be oriented “above” the other elements. The terms “below” or “beneath” can, therefore, encompass both an orientation of above and below.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the disclosure will be described with reference to the accompanying drawings.

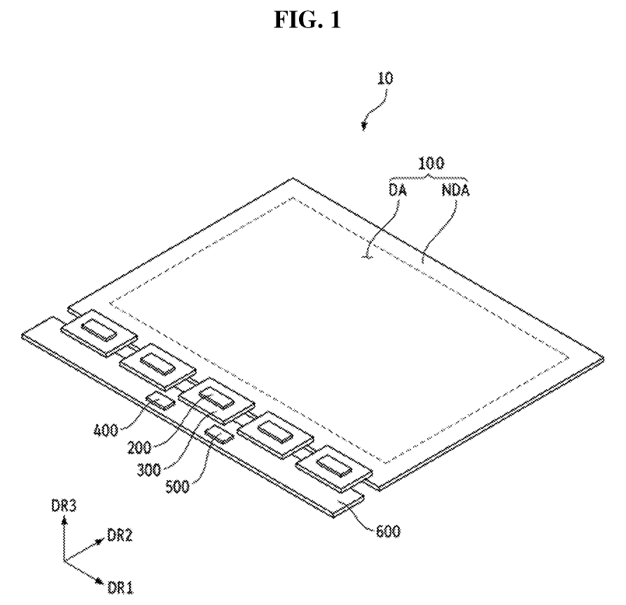

FIG. 1 is a perspective view of an embodiment of a display device of the disclosure.

Referring to FIG. 1, a display device 10 is for displaying moving images or still images. The display device 1 may be used as the display screen of portable electronic devices such as a mobile phone, a smart phone, a tablet personal computer (“PC”), a smart watch, a watch phone, a mobile communications terminal, an electronic notebook, an electronic book, a portable multimedia player (“PMP”), a navigation device and a ultra mobile PC (“UMPC”), as well as the display screen of various products such as a television, a notebook, a monitor, a billboard and the Internet of Things.

The display device 10 may be a light-emitting display device such as an organic light-emitting display device using organic light-emitting diodes, a quantum-dot light-emitting display device including a quantum-dot emissive layer, an inorganic light-emitting display device including an inorganic semiconductor, and a micro light-emitting display device using micro or nano light-emitting diodes (micro light-emitting diodes (“LEDs”) or nano LEDs). In the following description, an organic light-emitting display device is described in an embodiment of the display device 10. It is, however, to be understood that the disclosure is not limited thereto.

The display device 10 includes a display panel 100, a plurality of source driver circuits 200, a plurality of flexible circuit boards 300, a timing control circuit 400, a power supply circuit 500, and a circuit board 600.

The display panel 100 may be formed in a quadrangular plane, e.g., rectangular plane having longer sides in the first direction DR1 and shorter sides in a second direction DR2 intersecting the first direction DR1. Each of the corners where the longer side in the first direction DR1 meets the shorter side in the second direction DR2 may be rounded with a predetermined curvature or may be a right angle. The shape of the display panel 100 when viewed from the top is not limited to a quadrangular shape, but may be formed in a different polygonal shape, a circular shape, or an elliptical shape. The display panel 100 may be formed flat, but the disclosure is not limited thereto. In an embodiment, the display panel 100 may include curved portions which are formed at the left and right ends and have a constant curvature or varying curvatures, for example. In addition, the display panel 100 may be flexible so that it may be curved, bent, folded or rolled.

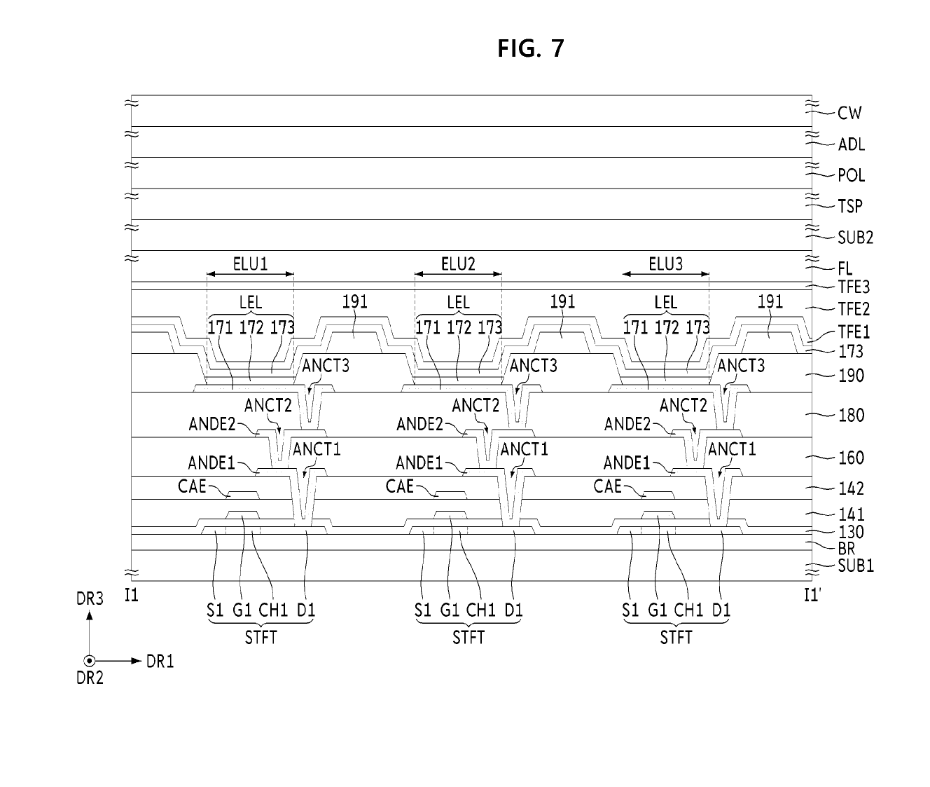

The display panel 100 may include a display area DA where images are displayed, and a non-display area NDA disposed around the display area DA. A first substrate SUB1 (refer to FIG. 7) of the display panel 100 may include a display area DA and a non-display area NDA.

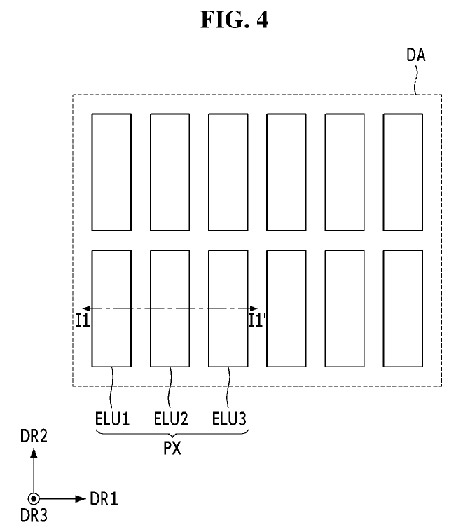

The display area DA may occupy most of the area of the display panel 100. The display area DA may be disposed at the center of display panel 100. A plurality of pixels PX (refer to FIG. 4) for displaying images may be arranged in the display area DA.

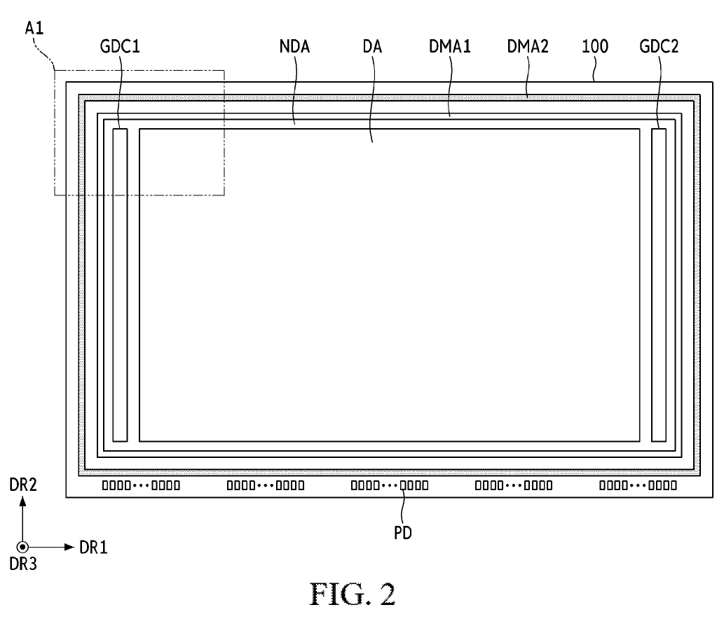

In the non-display area NDA, display pads PD (refer to FIG. 2) may be arranged to connect to the flexible circuit boards 300. The display pads PD (refer to FIG. 2) may be arranged at one edge of the display panel 100.

Each of the source driver circuits 200 may be implemented as an integrated circuit (“IC”) and may be attached to the respective flexible circuit boards 300, but the embodiments of the disclosure are not limited thereto. Each of the source driver circuits 200 may be attached on the display panel 100 by chip-on-glass (“COG”) technique, chip-on-plastic (“COP”) technique, or ultrasonic bonding.

The flexible circuit boards 300 may be arranged on the display pads PD (refer to FIG. 2) arranged at one edge of the display panel 100. Each of the flexible circuit boards 300 may be attached to the display pads PD (refer to FIG. 2) using a conductive adhesive, such as an anisotropic conductive film. Accordingly, the flexible circuit boards 300 may be electrically connected to signal lines of the display panel 100. The flexible circuit boards 300 may be flexible printed circuit boards, flexible films such as chip on films.

The timing control circuit 400 may generate timing control signals for controlling the timing of scan driver circuits GDC1 and GDC2 (refer to FIG. 2), an emission driver circuit, and the source driver circuits 200. The power supply circuit 500 may generate supply voltages for driving the display panel 100 in response to an input power from an external source. Each of the timing control circuit 400 and the power supply circuit 500 may be implemented as an IC and attached to the circuit board 600.

The circuit board 600 may be connected to one side of each of the flexible circuit boards 300. The circuit board 600 may be a rigid printed circuit board.

FIG. 2 is a view showing a layout of an embodiment of the display panel according to the disclosure.

Referring to FIG. 2, the display panel 100 includes the display pads PD, the first scan driver circuit GDC1, the second scan driver circuit GDC2, a first dam area DMA1, and a second dam area DMA2.

The display pads PD may be arranged at one edge of the display panel 100. The display pads PD may be sorted into groups. When the display device 10 includes five flexible circuit boards 300 as shown in FIG. 1, the display pads PD may be sorted into five groups. The display pads PD of each of the groups may be respectively associated with bumps of the corresponding flexible circuit boards 300. Therefore, the display pads PD of each of the groups may be electrically connected with the corresponding flexible circuit boards 300.

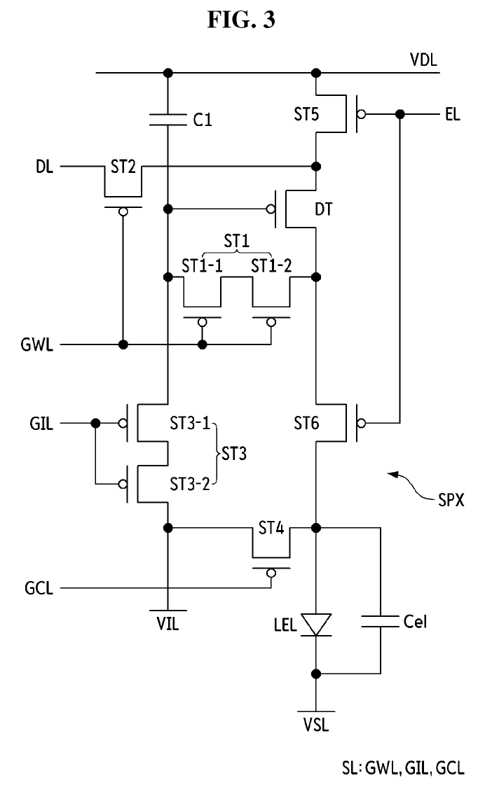

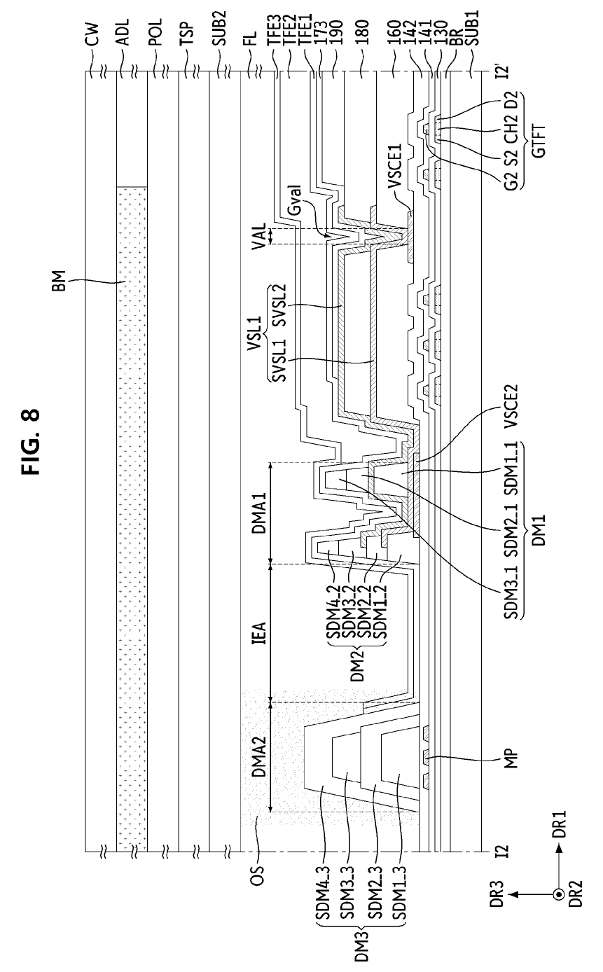

Some of the display pads PD may be electrically connected with data lines DL (refer to FIG. 3) arranged in the display area DA. Some others of the display pads PD may be electrically connected to the first scan driver circuit GDC1 and the second scan driver circuit GDC2. Still others of the display pads PD may be connected to a first voltage line VSL1 (refer to FIG. 8) on which a first supply voltage is applied.

The first voltage line VSL1 (refer to FIG. 8) may surround at least three sides of the display area DA. In an embodiment, the first voltage line VSL1 (refer to FIG. 8) may surround the left, upper and right sides of the display area DA, for example. In an alternative embodiment, the first voltage line VSL1 (refer to FIG. 8) may surround the left, upper, right and lower sides of the display area DA.

The first scan driver circuit GDC1 and the second scan driver circuit GDC2 may be electrically connected to scan lines SL (refer to FIG. 3) of the display area DA. Each of the first scan driver circuit GDC1 and the second scan driver circuit GDC2 may receive a scan timing control signal from the timing control circuit 400 and generate scan signals in response to the scan timing control signal. Each of the first scan driver circuit GDC1 and the second scan driver circuit GDC2 may sequentially output scan signals to the scan lines SL (refer to FIG. 3) of the display area DA.

The first scan driver circuit GDC1 may be placed in the non-display area NDA on a first side (e.g., left side) of the display panel 100. The second scan driver circuit GDC2 may be placed in the non-display area NDA on a second side (e.g., right side) of the display panel 100.

Each of the first scan driver circuit GDC1 and the second scan driver circuit GDC2 may be disposed between the display area DA and the first dam area DMA1. The first scan driver circuit GDC1 and the second scan driver circuit GDC2 may be arranged at the opposite edges of the display panel 100 in the first direction DR1, respectively.

The first dam area DMA1 includes one or more first and second dams (also collectively referred to as second area dams) DM1 and DM2 (refer to FIG. 7) to prevent an organic encapsulation layer TFE2 (refer to FIG. 7) from overflowing into the display pads PD. The first dam area DMA1 may surround the display area DA.

The second dam area DMA2 includes a third dam (also referred to as a first area dam) DM3 to prevent a filling material FL (refer to FIG. 7) between the first substrate SUB1 (refer to FIG. 7) and the encapsulation substrate SUB2 (refer to FIG. 7) from overflowing into the display pads PD. The second dam area DMA2 may surround the display area DA.

FIG. 3 is a circuit diagram showing an embodiment of a sub-pixel of a display panel.

Referring to FIG. 3, each of the sub-pixels SPX may be connected to two of the scan lines SL, one of the emission lines EL, and one of the data lines DL. The scan lines SL may include a write scan line GWL, an initialization scan line GIL, and a control scan line GCL. Different scan signals may be applied to the write scan line GWL, the initial scan line GIL and the control scan line GCL.

As shown in FIG. 3, the sub-pixel SPX may be connected to the write scan line GWL, the initialization scan line GIL, the control scan line GCL, the emission line EL, and the data line DL.

As shown in FIG. 3, the sub-pixel SPX includes a driving transistor DT, a light-emitting element LEL, switch elements, and a capacitor C1. The switch elements include first to sixth transistors ST1, ST2, ST3, ST4, ST5 and ST6.

The driving transistor DT includes a gate electrode, a first electrode, and a second electrode. The drain-source current Ids (hereinafter referred to as "driving current") of driving transistor DT flowing between the first electrode and the second electrode is controlled according to the data voltage applied to the gate electrode.

The light-emitting element LEL emits light as the driving current Ids flows therein. The amount of the light emitted from the light-emitting element LEL may be proportional to the driving current Ids.

The light-emitting element LEL may be an organic light-emitting diode including an anode electrode, a cathode electrode, and an organic emissive layer disposed between the anode electrode and the cathode electrode. In an alternative embodiment, the light-emitting element LEL may be an inorganic light-emitting element including an anode electrode, a cathode electrode, and an inorganic semiconductor disposed between the anode electrode and the cathode electrode. In an alternative embodiment, the light-emitting element LEL may be a quantum-dot light-emitting element including an anode electrode, a cathode electrode, and a quantum-dot emissive layer disposed between the anode electrode and the cathode electrode. In an alternative embodiment, the light-emitting element LEL may be a micro light-emitting diode.

The anode electrode of the light-emitting element LEL may be connected to the first electrode of the fourth transistor ST4 and the second electrode of the sixth transistor ST6, while the cathode electrode thereof may be connected to a first voltage supply line VSL. A parasitic capacitance Cel may be formed between the anode electrode and the cathode electrode of the light-emitting element LEL.

The capacitor C1 is formed between the second electrode of the driving transistor DT and a second voltage supply line VDL. One electrode of the capacitor C1 may be connected to the second electrode of the driving transistor DT while a remaining (the other) electrode thereof may be connected to the second voltage supply line VDL.

When the first electrode of each of the first to sixth transistors ST1, ST2, ST3, ST4, ST5 and ST6 and the driving transistor DT is a source electrode, the second electrode thereof may be a drain electrode. In an alternative embodiment, when the first electrode of each of the first to sixth transistors ST1, ST2, ST3, ST4, ST5 and ST6 and the driving transistor DT is a drain electrode, the second electrode thereof may be a source electrode.

The active layer of each of the first to sixth transistors ST1, ST2, ST3, ST4, ST5 and ST6 and the driving transistor DT may include or consist of one of poly silicon, amorphous silicon and oxide semiconductor. When the semiconductor layer of each of the first to sixth transistors ST1 to ST6 and the driving transistor DT includes or consists of poly silicon, a low-temperature poly silicon (“LTPS”) process may be employed.

Although the first to sixth transistors ST1, ST2, ST3, ST4, ST5 and ST6 and the driving transistor DT are of p-type metal oxide semiconductor field effect transistors (“MOSFETs”) in FIG. 3, this is merely illustrative. They may be of n-type MOSFETs. In an embodiment, the first transistor ST1 may have dual transistors ST1-1 and ST1-2, and the third transistor ST3 may have dual transistors ST3-1 and ST3-2, but the disclosure is not limited thereto.

Moreover, a first supply voltage from the first voltage supply line VSL, a second supply voltage from the second voltage supply line VDL, and a third supply voltage from a third voltage supply line VIL may be determined based on the characteristics of the driving transistor DT, the characteristics of the light-emitting element LEL, etc.

FIG. 4 is a layout diagram showing an embodiment of the display area of FIG. 2 in detail.

Referring to FIG. 4, a plurality of pixels PX may be arranged in a matrix. Each of the plurality of pixels PX may include a first light-emitting unit ELU1 of a first sub-pixel SPX1, a second light-emitting unit ELU2 of a second sub-pixel SPX2, and a third light-emitting unit ELU3 of a third sub-pixel SPX3.

In each of the plurality of pixels PX, the first light-emitting unit ELU1, the second light-emitting unit ELU2 and the third light-emitting unit ELU3 may be arranged in stripes. In an embodiment, in each of the plurality of pixels PX, the first light-emitting unit ELU1, the second light-emitting unit ELU2 and the third light-emitting unit ELU3 may be arranged in the first direction DR1, for example.

The first light-emitting unit ELU1 may output a first light, the second light-emitting unit ELU2 may output a second light, and the third light-emitting unit ELU3 may output a third light. The first light may be light of a blue wavelength range, the second light may be light of a green wavelength range, and the third light may be light of a red wavelength range. In an embodiment, the blue wavelength range may refer that the main peak wavelength of light lies in the wavelength range of approximately 370 nanometers (nm) to 460 nm, the green wavelength range may refer that the main peak wavelength of light lies in the wavelength range of approximately 480 nm to 560 nm, and the red wavelength range may refer to that the main peak wavelength of light lies in the wavelength range of approximately 600 nm to 750 nm, for example.

Although each of the plurality of pixels PX includes three light-emitting units ELU1, ELU2 and ELU3 in the example shown in FIG. 4, the embodiments of the disclosure are not limited thereto. In an embodiment, each of the plurality of pixels PX may include four light-emitting units, for example. In this instance, the first light-emitting unit may output the first light, the second light-emitting unit and the fourth light-emitting unit may output the second light, and the third light-emitting unit may output the third light. In an alternative embodiment, the first light-emitting unit may output the first light, the second light-emitting unit may output the second light, the third light-emitting unit may output the third light, and the fourth light-emitting unit may output the fourth light. The fourth light may be white light. In addition, in each of the plurality of pixels PX, the first light-emitting unit, the second light-emitting unit, the third light-emitting unit and the fourth light-emitting unit may be arranged in stripes or the Pentile^{®} matrix.

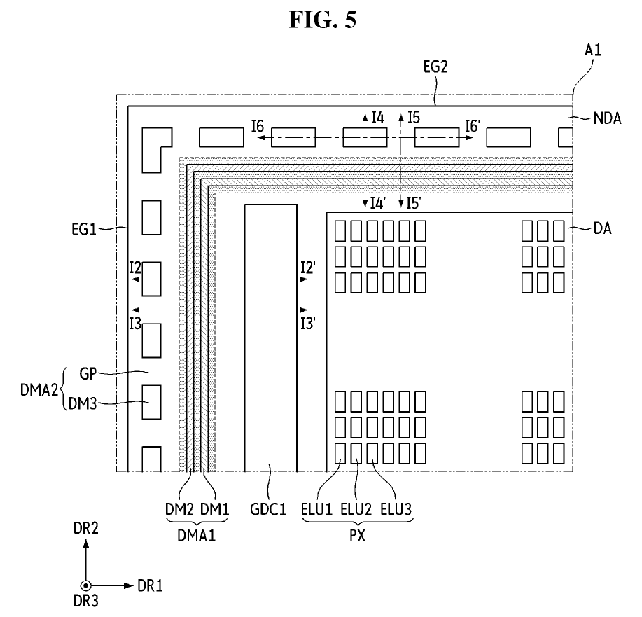

FIG. 5 is a view showing a layout of an embodiment of area A1 of FIG. 2. FIG. 5 is a view showing a layout of the non-display area NDA at the corner where the left and upper sides of the display panel 100 of FIG. 2 meet each other.

Referring to FIGS. 2 and 5, the first scan driver circuit GDC1, the first dam area DMA1 and the second dam area DMA2 may be disposed in the left non-display area NDA of the display panel 100. The first dam area DMA1 and the second dam area DMA2 may be disposed in the upper non-display area NDA of the display panel 100.

On the left side of the display panel 100, the first scan driver circuit GDC1 may be placed between the display area DA and the first dam area DMA1.

The first dam area DMA1 may be disposed between the first scan driver circuit GDC1 and the second dam area DMA2. The first dam area DMA1 may include a first dam DM1 and a second dam DM2.

On the left side of the display panel 100, the first dam DM1 may be disposed between the second dam DM2 and the first scan driver circuit GDC1. On the upper side of the display panel 100, the first dam DM1 may be disposed between the second dam DM2 and the display area DA.

The first dam DM1 disposed on the left side of the display panel 100 may be extended in the second direction DR2 and may be continuous without being disconnected. The first dam DM1 disposed on the right side of the display panel 100 may also be extended in the second direction DR2 and may be continuous without being disconnected.

The first dam DM1 disposed on the upper side of the display panel 100 may be extended in the first direction DR1 and may be continuous without being disconnected. The first dam DM1 disposed on the lower side of the display panel 100 may also be extended in the first direction DR1 and may be continuous without being disconnected.

At each of the corners of the display panel 100, the first dam DM1 extended in the first direction DR1 and the first dam DM2 extended in the second direction DR2 meet each other. Accordingly, the first dam DM1 may surround the display area DA of the display panel 100. In an embodiment, the first dam DM1 extended in the second direction DR2 on the left side of the display panel 100 and the first dam DM1 extended in the first direction DR1 on the upper side of the display panel 100 may meet at the corner where the left and upper sides of the display panel 100 meet each other, for example.

On the left side of the display panel 100, the second dam DM2 may be disposed between the first dam DM1 and the second dam area DMA2. The second dam DM2 disposed on the left side of the display panel 100 may be extended in the second direction DR2 and may be continuous without being disconnected. In addition, the second dam DM2 disposed on the right side of the display panel 100 may also be extended in the second direction DR2 and may be continuous without being disconnected.

On the upper side of the display panel 100, the second dam DM2 may be disposed between the first dam DM1 and the second dam area DMA2. The second dam DM2 disposed on the upper side of the display panel 100 may be extended in the first direction DR1 and may be continuous without being disconnected. In addition, the second dam DM2 disposed on the lower side of the display panel 100 may also be extended in the first direction DR1 and may be continuous without being disconnected.

At each of the corners of the display panel 100, the second dam DM2 extended in the first direction DR1 and the second dam DM2 extended in the second direction DR2 meet each other. Accordingly, the second dam DM2 may surround the display area DA of the display panel 100. In an embodiment, the second dam DM2 extended in the second direction DR2 on the left side of the display panel 100 and the second dam DM2 extended in the first direction DR1 on the upper side of the display panel 100 may meet at the corner where the left and upper sides of the display panel 100 meet each other, for example.

The second dam area DMA2 may be disposed at the outermost position of the non-display area NDA of the display panel 100, and may surround the display area DA and the first dam area DMA1. The distance between the second dam area DMA2 and a first (e.g., left) edge EG1 of the display panel 100 may be smaller than the distance between the second dam area DMA2 and the second dam DM2.

The second dam area DMA2 may include a plurality of third dams DM3 and a plurality of gaps GP. The plurality of third dams DM3 may be structures to prevent a filling member FL (refer to FIG. 7) from overflowing into the outside of the display panel 100.

The third dams DM3 may be spaced apart from one another. There may be a gap GP between two neighboring (adjacent) ones of the third dams DM3. The gaps GP may be filled with a sealing member OS (refer to FIG. 8) formed on a surface of the second substrate SUB2 when bonded to the second substrate SUB2. Bubbles generated when the filling member FL (refer to FIG. 7) fills between the first substrate SUB1 and the second substrate SUB2 may be released through the gaps GP before the second substrate SUB2 is completely bonded. In other words, the bubbles BUB of the filling member FL may be released before the sealing member OS contacts the second inter-dielectric layer 142.

The third dams DM3 on the left and right sides of the display panel 100 may be arranged in the second direction DR2 with the gaps GP between them. The length of each of the third dams DM3 on the left and right sides of the display panel 100 in the first direction DR1 may be smaller than the length of each of the third dams DM3 in the second direction DR2. In addition, the length of each of the third dams DM3 in the second direction DR2 may be substantially equal to the length of the gaps GP in the second direction DR2, but the disclosure is not limited thereto.

The third dams DM3 on the upper and lower sides of the display panel 100 may be arranged in the first direction DR1 with the gaps GP between them. The length of each of the third dams DM3 on the upper and lower sides of the display panel 100 in the second direction DR2 may be smaller than the length of each of the third dams DM3 in the first direction DR1. In addition, the length of each of the third dams DM3 in the first direction DR1 may be substantially equal to the length of the gaps GP in the first direction DR1, but the disclosure is not limited thereto.

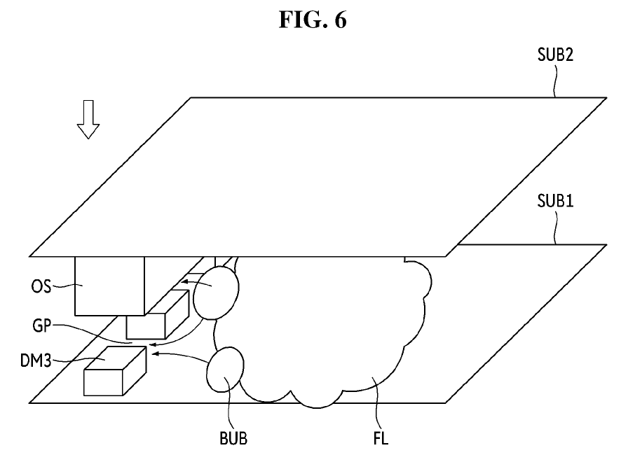

FIG. 6 is a view schematically showing bubbles BUB being released which are generated as the space between the first substrate SUB1 and the second substrate SUB2 is filled with the filling member FL.

Referring to FIG. 6, the sealing member OS is placed on the surface of the second substrate SUB2 that faces the first substrate SUB1. The sealing member OS may overlap with the second dam area DMA2 of the first substrate SUB1 in the third direction DR3. The sealing member OS bonds the first substrate SUB1 to the second substrate SUB2 at their edges, thereby preventing overflow of the filling member FL and preventing the permeation of oxygen or moisture from the outside.

When bonding the first substrate SUB1 to the second substrate SUB2, the filling member FL is used to fill between the first substrate SUB1 and the second substrate SUB2, and bubbles BUB generated during this process may be released through the gaps GP. In contrast, when the second dam area DMA2 includes a linearly connected dam that surrounds the display area DA, like the first dam DM1 and the second dam DM2, then there is no gap for bubbles BUB generated during the process of bonding the first substrate SUB1 to the second substrate SUB2 to be released, making it difficult to discharge the bubbles BUB. When the display device 10 includes bubbles BUB which are not released, it may be determined that the display device 10 is defective.

As shown in FIG. 6, when there are gaps GP between the third dams DM3, the bubbles BUB may be released through the gaps GP. That is to say, it is possible to prevent the bubbles BUB from being recognized which are generated during the process of filling the space between the first substrate SUB1 and the second substrate SUB2 with the filling member FL.

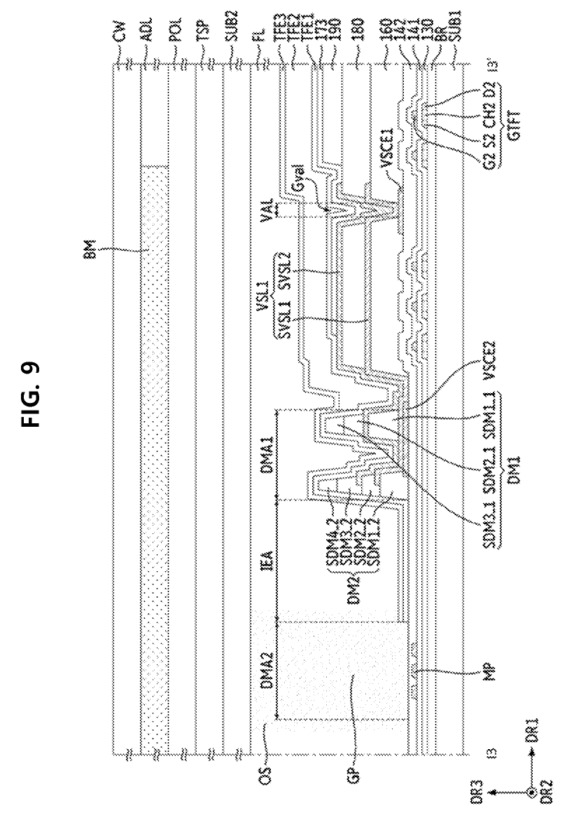

FIG. 7 is a cross-sectional view showing an embodiment of the display panel 100, taken along line I1 – I1' of FIG. 4. FIG. 8 is a cross-sectional view showing an embodiment of the display panel 100, taken along line I2 – I2' of FIG. 5. FIG. 9 is a cross-sectional view showing an embodiment of the display panel 100, taken along line I3 – I3' of FIG. 5.

FIG. 7 shows a cross-section of a plurality of sub-pixels SPX arranged in the display area DA. FIGS. 8 and 9 show cross-sections of the left non-display area NDA of the display panel 100. Specifically, FIG. 8 shows a cross-section of the second dam area DMA2 including a third dam DM3, and FIG. 9 shows a cross-section of the second dam area DMA2 including a gap GP.

Referring to FIGS. 7 and 9, a barrier layer BR may be disposed on the first substrate SUB1. The first substrate SUB1 may include or consist of an insulating material such as glass and a polymer resin, or may be a silicon wafer

The barrier layer BR is for protecting a plurality of pixel transistors STFT, a plurality of scan transistors GTFT, and an emissive layer 172 of an emission material layer EML from the moisture permeating through the first substrate SUB1 which is vulnerable to permeation of moisture. The barrier layer BR may be made up of multiple inorganic layers stacked on one another alternately. In an embodiment, the barrier layer BR may be made up of multiple layers in which one or more inorganic layers of a silicon nitride layer, a silicon oxynitride layer, a silicon oxide layer, a titanium oxide layer and an aluminum oxide layer are alternately stacked on one another, for example.

On the barrier layer BR, the pixel transistors STFT of the sub-pixels SPX and the scan transistors GTFT of the scan driver circuits GDC1 and GDC2 may be arranged. The pixel transistors STFT may be arranged in the display area, and the scan transistors GTFT may be arranged in the non-display area.

Each of the pixel transistors STFT includes a first channel CH1, a first source electrode S1, a first drain electrode D1 and a first gate electrode G1. Each of the scan transistors GTFT includes a second channel CH2, a second source electrode S2, a second drain electrode D2 and a second gate electrode G2.

An active layer ACT may be disposed on the barrier layer BR. The active layer ACT may include the first channel CH1, the first source electrode S1 and the first drain electrode D1 of the pixel transistor STFT, and the second channel CH2, the second source electrode S2 and the second drain electrode D2 of the scan transistor GTFT.

The first channel CH1 of the pixel transistor STFT and the second channel CH2 of the scan transistor GTFT may include polycrystalline silicon, monocrystalline silicon, low-temperature polycrystalline silicon, amorphous silicon, or oxide semiconductor.

The first channel CH1 of the pixel transistor STFT may be defined as a channel region that overlaps with the first gate electrode G1 in the third direction DR3, which is the thickness direction of the first substrate SUB1. The first source electrode S1 and the first drain electrode D1 of the pixel transistor STFT are regions that do not overlap with the first gate electrode G1 in the third direction DR3, and may have conductivity by doping ions or impurities into a silicon semiconductor or an oxide semiconductor.

The second channel CH2 of the scan transistor GTFT may be defined as a channel region that overlaps with the second gate electrode G2 in the third direction DR3, which is the thickness direction of the first substrate SUB1. The second source electrode S2 and the second drain electrode D2 of the scan transistor STFT are regions that do not overlap with the second gate electrode G2 in the third direction DR3, and may have conductivity by doping ions or impurities into a silicon semiconductor or an oxide semiconductor.

The gate insulator 130 may be disposed on the active layer ACT. The gate insulator 130 may include an inorganic layer, e.g., a silicon nitride layer, a silicon oxynitride layer, a silicon oxide layer, a titanium oxide layer, or an aluminum oxide layer.

The first gate metal layer GTL1 may be disposed on the gate insulator 130. The first gate metal layer GTL1 may include a plurality of first gate electrodes G1 and a plurality of second gate electrodes G2. Each of the first gate electrodes G1 may overlap with the first channel CH1 of the pixel transistor STFT in the third direction DR3, and each of the second gate electrodes G2 may overlap with the second channel CH2 of the scan transistor GTFT in the third direction DR3.

The first gate metal layer GTL1 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The first inter-dielectric layer 141 may be disposed over the first gate metal layer GTL1. The first inter-dielectric layer 141 may include an inorganic layer, e.g., a silicon nitride layer, a silicon oxynitride layer, a silicon oxide layer, a titanium oxide layer, or an aluminum oxide layer. The first inter-dielectric layer 141 may be made up of multiple inorganic films.

The second gate metal line GTL2 may be disposed on the first inter-dielectric layer 141. The second gate metal layer GTL2 may include a plurality of capacitor electrodes CAE and a plurality of metal patterns MP. The capacitor electrodes CAE may be arranged in the display area DA, and the metal patterns MP may be arranged in the non-display area NDA.

Specifically, each of the capacitor electrodes CAE may overlap with the first gate electrode G1 of the pixel transistor STFT in the third direction DR3. Since the first inter-dielectric layer 141 has a dielectric constant, a capacitor may be formed by the capacitor electrode CAE, the first gate electrode G1, and the first inter-dielectric layer 141 disposed between them.

The metal patterns MP may be arranged in the second dam area DMA2 in the third direction DR3. That is to say, the metal patterns MP may overlap with the third dam DM3 or the gap GP in the third direction DR3. The metal patterns MP may be voltage lines or signal lines. In an embodiment, a first supply voltage identical to the voltage applied to the first voltage line VSL1 may be applied to the metal patterns MP, for example.

The second gate metal layer GTL2 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The second inter-dielectric layer 142 may be disposed over the second gate metal layer GTL2. The second inter-dielectric layer 142 may include an inorganic layer, e.g., a silicon nitride layer, a silicon oxynitride layer, a silicon oxide layer, a titanium oxide layer, or an aluminum oxide layer. The second inter-dielectric layer 142 may include or consist of a plurality of inorganic layers.

A first data metal layer DTL1 may be placed on the second inter-dielectric layer 142. The first data metal layer DTL1 may include a first anode connection electrode ANDE1, a first voltage connection electrode VSCE1, and a second voltage connection electrode VSCE2. The first data metal layer DTL1 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The first anode connection electrode ANDE1 may be connected to the first drain electrode D1 of the pixel transistor STFT through a first connection contact hole ANCT1 that penetrates the gate insulator 130, the first inter-dielectric layer 141 and the second inter-dielectric layer 142 in the display area DA. The first voltage connection electrode VSCE1 in the non-display area NDA may be in line with a groove Gval of an inorganic area VAL penetrating the first planarization layer 160 and the second planarization layer 180 in the third direction DR3. The second voltage connection electrode VSCE2 in the first dam area DMA1 may be disposed on the second inter-dielectric layer 142 without being covered by the first planarization layer 160.

The first planarization layer 160 may be placed over the first data metal layer DTL1 to provide a flat surface over the height differences created by the pixel transistor STFT and the scan transistor GTFT. The first planarization layer 160 may include an organic layer such as an acryl resin, an epoxy resin, a phenolic resin, a polyamide resin and a polyimide resin.

A second data metal layer DTL2 may be placed on the first planarization layer 160. The second data metal layer DTL2 may include a second anode connection electrode ANDE2, and a first sub-voltage line SVSL1 of the first voltage line VSL1. The second data metal layer DTL2 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The second anode connection electrode ANDE2 may be connected to the first anode connection electrode ANDE1 through a second connection contact hole ANCT2 penetrating the first planarization layer 160.

The first sub-voltage line SVSL1 may be placed on the first planarization layer 160. The first sub-voltage line SVSL1 may be connected to the first voltage connection electrode VSCE1 exposed in the groove Gval of the inorganic area VAL. The first sub-voltage line SVSL1 may be disposed on the second voltage connection electrode VSCE2 in the first dam area DMA1.

The groove Gval penetrating the first planarization layer 160 and the second planarization layer 180 may be disposed in the inorganic area VAL. In the inorganic area VAL, the first planarization layer 160 and the second planarization layer 180 next (adjacent) to a first edge EG1 of the display panel 100 may be spaced apart from the first planarization layer 160 and the second planarization layer 180 next (adjacent) to the display area DA. The first planarization layer 160 and the second planarization layer 180 may be disconnected in the inorganic area VAL. Therefore, even when oxygen or moisture permeates through the first planarization layer 160 and the second planarization layer 180 at the first edge EG1 of the display panel 100, It is possible to prevent the oxygen or moisture from being transferred to the first planarization layer 160 and the second planarization layer 180 next (adjacent) to the display area DA and affecting the emissive layer 172.

The second planarization layer 180 may be disposed on the second data metal layer DTL2. The second planarization layer 180 may be formed as an organic layer such as an acryl resin, an epoxy resin, a phenolic resin, a polyamide resin and a polyimide resin.

As shown in FIG. 7, light-emitting elements LEL and a pixel-defining layer 190 may be arranged on the second planarization layer 180 of the display area DA. Each of the light-emitting elements LEL includes a pixel electrode 171, an emissive layer 172, and a common electrode 173.

The pixel electrode 171 may be disposed on the second planarization layer 180. The pixel electrode 171 may be connected to the second anode connection electrode ANDE2 through a third connection contact hole ANCT3 penetrating the second planarization layer 180.

In the top-emission structure in which light exits from the emissive layer 172 toward the common electrode 173, the pixel electrode 171 may include or consist of a metal material having a relatively high reflectivity such as a stack structure of aluminum and titanium (Ti / Al / Ti), a stack structure of aluminum and indium tin oxide (“ITO”) (ITO / Al / ITO), an APC alloy and a stack structure of APC alloy and ITO (ITO / APC / ITO). The APC alloy is an alloy of silver (Ag), palladium (Pd) and copper (Cu).

In order to define the first light-emitting unit ELU1, the second light-emitting unit ELU2 and the third element unit ELU3, the pixel-defining layer 190 may partition the pixel electrodes 171 on the second planarization layer 180. The pixel-defining layer 190 may be formed to cover the edges of the pixel electrode 171.

A spacer 191 may be placed on the pixel-defining layer 190 to stably support the mask in the process of depositing the emissive layer EL.

The pixel-defining layer 190 and the spacer 191 may include or consist of an organic layer such as an acryl resin, an epoxy resin, a phenolic resin, a polyamide resin and a polyimide resin.

In each of the first light-emitting unit ELU1, the second light-emitting unit ELU2 and the third light-emitting unit ELU3, the pixel electrode 171, the emissive layer 172 and the common electrode 173 are stacked on one another sequentially, so that holes from the pixel electrode 171 and electrons from the common electrode 173 are combined with each other in the emissive layer 172 to emit light.

The emissive layer 172 may be disposed on the pixel electrode 171 and the pixel-defining layer 190. The emissive layer 172 may include an organic material to emit light of a particular color. In an embodiment, the emissive layer 172 may include a hole transporting layer, an organic material layer, and an electron transporting layer, for example.

The common electrode 173 may be disposed on the emissive layer 172. The common electrode 173 may cover the emissive layer 172. The common electrode 173 may be a common layer formed commonly across the first light-emitting unit ELU1, the second light-emitting unit ELU2, and the third light-emitting unit ELU3. A capping layer may be formed on the common electrode 173.

In the top-emission organic light-emitting diode, the common electrode 173 may include a transparent conductive material (“TCP”) such as ITO and IZO that may transmit light, or a semi-transmissive conductive material such as magnesium (Mg), silver (Ag) and an alloy of magnesium (Mg) and silver (Ag). When the common electrode 173 includes or consists of a semi-transmissive metal material, the light extraction efficiency may be increased by microcavities.

As shown in FIGS. 8 and 9, a second sub-voltage line SVSL2 of the first voltage line VSL1 may be placed on the second planarization layer 180 in the non-display area NDA. The second sub-voltage line SVSL2 may be disposed on the first sub-voltage line SVSL1 in the groove Gval of the inorganic area VAL. The second sub-voltage line SVSL2 may be disposed on the first sub-voltage line SVSL1 in the first dam area DMA1.

In an embodiment, the second voltage connection electrode VSCE2, the first sub-voltage line SVSL1 and the second sub-voltage line SVSL2 may be sequentially stacked in the first dam area DMA1, for example.

The common electrode 173 may be placed on the second planarization layer 180 exposed and not covered by the pixel-defining layer 190 and the pixel-defining layer 190. The common electrode 173 may be connected to the second sub-voltage line SVSL2 in the groove Gval of the inorganic area VAL. The common electrode 173 may be placed on the side walls of the groove Gval of the inorganic area VAL. Therefore, when external light is incident on the groove Gval of the inorganic area VAL, it may be unpredictably reflected by the common electrode 173 placed on the side walls of the groove Gval of the inorganic area VAL.

The encapsulation layer TFEL may be disposed on the common electrode 173. The encapsulation layer TFEL includes at least one inorganic film to prevent permeation of oxygen or moisture into the emission material layer EML. In addition, the encapsulation layer TFEL includes at least one organic layer to protect the emission material (also referred to as a light-emitting element layer) EML from foreign substances such as dust. In an embodiment, the encapsulation layer TFEL includes a first inorganic encapsulation layer TFE1, an organic encapsulation layer TFE2 and a second inorganic encapsulation layer TFE3, for example.

The first inorganic encapsulation layer TFE1 may be disposed on the common electrode 173, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation layer TFE2 may be an organic film such as an acryl resin, an epoxy resin, a phenolic resin, a polyamide resin, a polyimide resin, etc.

The first dam area DMA1 and the second dam area DMA2 may be disposed toward the first (e.g., left) edge EG1 (refer to FIG. 5) in the non-display area NDA.

The first dam area DMA1 may include a first dam DM1 and a second dam DM2. The first dam DM1 and the second dam DM2 may be arranged on the first voltage line VSL1.

The first dam DM1 and the second dam DM2 may be structures for preventing the organic encapsulation layer TFE2 from overflowing into the first (e.g., left) edge EG1 of the display panel 100. The first dam DM1 and the second dam DM2 may be structures for confining the organic encapsulation layer TFE2.

The first dam DM1 may include a first sub-dam SDM1_1, a second sub-dam SDM2_1 and a third sub-dam SDM3_1 sequentially stacked on the first voltage line VSL1. The first sub-dam SDM1_1 may include or consist of the same material as that of the second planarization layer 180, the second sub-dam SDM2_1 may include or consist of the same material as that of the pixel-defining layer 190, and the third sub-dam SDM3_1 may include or consist of the same material as that of the spacer 191.

The second sub-voltage line SVSL2 may be placed on the first sub-dam SDM1_1 of the first dam DM1. The second sub-voltage line SVSL2 may cover the first sub-dam SDM1_1 of the first dam DM1. In an embodiment, the second sub-voltage line SVSL2 may be placed on the upper surface and side surfaces of the first sub-dam SDM1_1 of the first dam DM1, for example. The second sub-dam SDM2_1 of the first dam DM1 may be placed on the second sub-voltage line SVSL2.

The second dam DM2 may include a first sub-dam SDM1_2, a second sub-dam SDM2_2, a third sub-dam SDM3_2 and a fourth sub-dam SDM4_2 sequentially stacked on the second inter-dielectric layer 142. The first sub-dam SDM1_2 may include or consist of the same material as that of the first planarization layer 160, and the second sub-dam SDM2_2 may include or consist of the same material as that of the second planarization layer 180. The third sub-dam SDM3_2 may include or consist of the same material as that of the pixel-defining layer 190, and the fourth sub-dam SDM4_2 may include or consist of the same material as that of the spacer 191.

The first sub-dam SDM1_2 of the second dam DM2 may be placed on the second voltage connection electrode VSCE2. In addition, the first sub-voltage line SVSL1 may be disposed on the first sub-dam SDM1_2 of the second dam DM2, the second sub-dam SDM2_2 of the second dam DM2 may be disposed on the first sub-voltage line SVSL1, and the third sub-dam SDM3_2 of the second dam DM2 may be disposed on the second sub-voltage line SVSL2.

On the outer side of the second dam DM2, the first inorganic encapsulation layer TFE1 and the second inorganic encapsulation layer TFE3 contact each other, creating an inorganic encapsulation area IEA including only the inorganic layer. No organic layer is disposed in the inorganic encapsulation area IEA. The display area DA is surrounded by the inorganic encapsulation area IEA, thereby preventing external oxygen or moisture from permeating into the emissive layer of the display area DA. The inorganic encapsulation area IEA may be closer to the first dam area DMA1 than the inorganic area VAL.

The second dam area DMA2 may be spaced apart from the first dam area DMA1 toward the first (e.g., left) edge EG1 (refer to FIG. 5). That is, the second dam area DMA2 may be close to the first (e.g., left) edge EG1 (refer to FIG. 5). The minimum distance between the third dam DM3 of the second dam area DMA2 and the first dam area DMA1 may be greater than the minimum distance between the first dam DM1 and the second dam DM2.

The third dam DM3 and the sealing member OS may be arranged in the second dam area DMA2. The third dam DM3 and the sealing member OS may be structures for preventing overflow of the filling member FL between the first substrate SUB1 and the second substrate SUB2.

The third dam DM3 may include a first sub-dam SDM1_3, a second sub-dam SDM2_3, a third sub-dam SDM3_3 and a fourth sub-dam SDM4_3 sequentially stacked on the second inter-dielectric layer 142. The first sub-dam SDM1_3 may include or consist of the same material as that of the first planarization layer 160, and the second sub-dam SDM2_3 may include or consist of the same material as that of the second planarization layer 180. The third sub-dam SDM3_3 may include or consist of the same material as that of the pixel-defining layer 190, and the fourth sub-dam SDM4_3 may include or consist of the same material as that of the spacer 191.

Since the width of the second sub-dam SDM2_3 is larger than that of the first sub-dam SDM1_3, the second sub-dam SDM2_3 may cover the side surfaces of the first sub-dam SDM1_3. The width of the fourth sub-dam SDM4_3 is larger than that of the first to third sub-dams SDM1_3, SDM2_3 and SDM3_3, so that the fourth sub-dam SDM4_3 may cover the side surfaces of the first to third sub-dams SDM1_3, SDM2_3 and SDM3_3. The widths of the first to fourth sub-dams SDM1_3, SDM2_3, SDM3_3 and SDM4_3 may be lengths defined in the first direction DR1 or the second direction DR2. It should be noted that the order in which the first to fourth sub-dams SDM1_3, SDM2_3, SDM3_3 and SDM4_3 of the third dam DM3 are stacked on one another is not limited thereto.

Since the first dam DM1 includes three sub-dams while the second dam DM2 and the third dam DM3 include four sub-dams, the height of the third dam DM3 may be larger than the height of the first dam DM1 and equal to the height of the second dam DM2. The heights of the first to third dams DM1, DM2 and DM3 may be the lengths of the first to third dams DM1, DM2 and DM3 in the third direction DR3.

The first inorganic encapsulation layer TFE1 and the second inorganic encapsulation layer TFE3 may contact each other on a part of the side surface of the third dam DM3.

The sealing member OS may be placed in line with the second dam area DMA2 in the third direction DR3. The length of the sealing member OS in the first direction DR1 may be greater than the length of the second dam area DMA2 in the first direction DR1. In an embodiment, the sealing member OS may surround the upper and side surfaces of the third dam DM3, for example. Specifically, the sealing member OS may be placed on the first inorganic encapsulation layer TFE1 and the second inorganic encapsulation layer TFE3, which are disposed on the part of the side surface of the third dam DM3.

Since the third dam DM3 is desired to support the sealing member OS, the length of the third dam DM3 in the first direction DR1 may be similar to the length of the sealing member OS in the first direction DR1. That is to say, the length of the third dam DM3 in the first direction DR1 may be larger than the lengths of the first dam DM1 and the second dam DM2 in the first direction DR1.

The sealing member OS may include or consist of a material including or consisting of epoxy or acrylic. The sealing member OS may be cured by ultraviolet rays to seal the space between the first substrate SUB1 and the second substrate SUB2.

As shown in FIG. 9, the gap GP may be a space or an area between neighboring (adjacent) ones of the third dams DM3 in the second dam area DMA2. Therefore, the third dam DM3 may not be disposed in the gap GP. The gap GP may be filled with the sealing member OS. That is to say, the sealing member OS of the gap GP in the second dam area DMA2 may contact the second inter-dielectric layer 142.

The filling member FL may be placed on the encapsulation layer TFEL. The filling member FL may work as an adhesive for bonding the second substrate SUB2 on the first substrate SUB1. The filling member FL may improve the strength of the display panel 100 by filling between the first substrate SUB1 and the second substrate SUB2. The filling member FL may be a material including or consisting of silicone.

The second substrate SUB2 may be placed on the filling member FL. The second substrate SUB2 may include or consist of an insulating material such as glass and a polymer resin.

A touch screen panel TSP for detecting touch may be placed on the second substrate SUB2. A polarizing film POL may be placed on the touch screen panel TSP to prevent degradation of visibility due to external light. The polarizing film POL may include a first base member, a linear polarizer, a retardation film such as a λ/4 (quarter-wave) plate, and a second base member. The polarizing film POL may be replaced by another anti-reflection layer, such as a color filter layer including a plurality of color filters.

The cover window CW may be placed on the polarizing film POL. The cover window CW may be attached on the polarizing film POL by a transparent adhesive member ADL such as an optically clear adhesive (“OCA”) film and an optically clear resin (“OCR”). A light-blocking layer BM may be placed on a surface of the cover window CW in the non-display area NDA. The light-blocking layer BM may overlap the groove Gval of the inorganic area VAL in the third direction DR3. Therefore, it is possible to prevent external light from being incident on the groove Gval of the inorganic area VAL. Therefore, it is possible to prevent external light from being unpredictably reflected by the common electrode 173 disposed on the side walls of the groove Gval of the inorganic area VAL, and thus, it is possible to reduce or prevent the visibility of the image displayed in the display area DA from degrading.

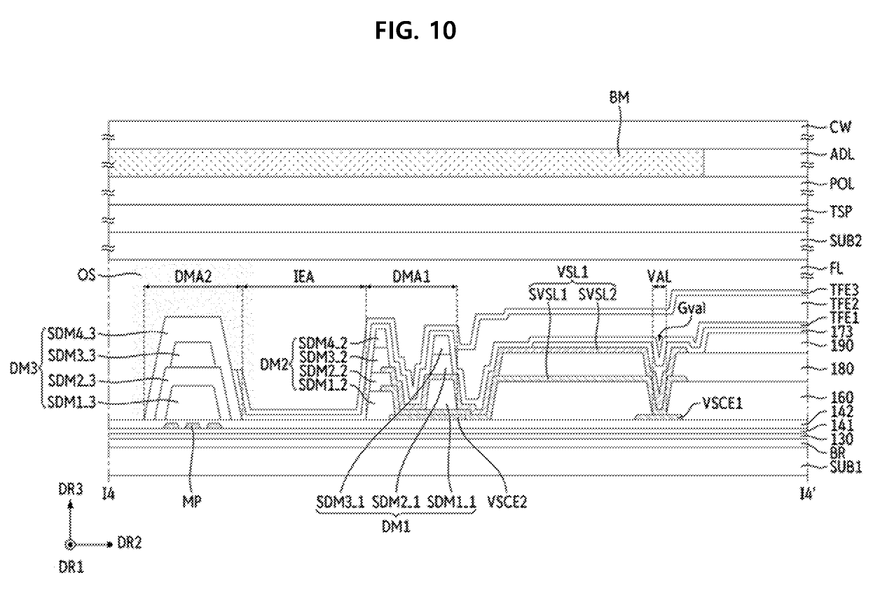

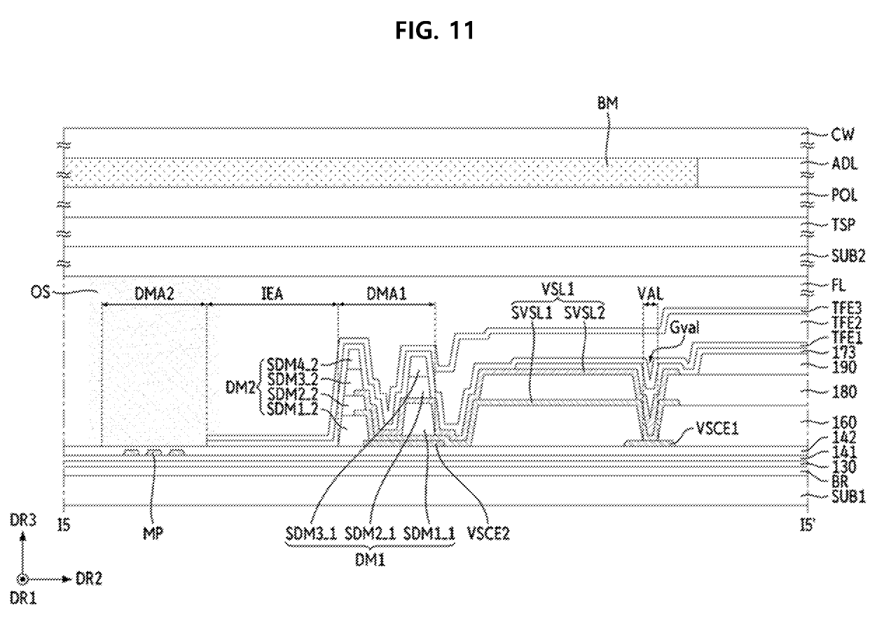

FIG. 10 is a cross-sectional view showing an embodiment of the display panel 100, taken along line I4 – I4' of FIG. 5. FIG. 11 is a cross-sectional view showing an embodiment of the display panel 100, taken along line I5 – I5' of FIG. 5.

FIGS. 10 and 11 are cross-sectional views showing embodiments of the upper non-display area NDA of the display panel 100. Specifically, FIG. 10 is a cross-sectional view showing an embodiment of the second dam area DMA2 including a third dam DM3, and FIG. 11 is a cross-sectional view showing an embodiment of the second dam area DMA2 including a gap GP. The following descriptions will focus on differences between the embodiment of FIGS. 7 to 9 and the embodiment of FIGS. 10 and 11 and the redundant descriptions will be omitted.

Referring to FIGS. 10 and 11, since the scan driver circuits GDC1 and GDC2 are not arranged on the upper side of the display panel 100, the scan transistor GTFT shown in FIGS. 8 and 9 is not disposed.

The second dam area DMA2 may be spaced apart from the first dam area DMA1 toward an upper edge EG2 (refer to FIG. 5). The third dam DM3 and the sealing member OS may be arranged in the second dam area DMA2.

The third dam DM3 and the sealing member OS may be structures for preventing overflow of the filling member FL between the first substrate SUB1 and the second substrate SUB2.

The third dam DM3 may include a first sub-dam SDM1_3, a second sub-dam SDM2_3, a third sub-dam SDM3_3 and a fourth sub-dam SDM4_3 sequentially stacked on the second inter-dielectric layer 142. The first sub-dam SDM1_3 may include or consist of the same material as that of the first planarization layer 160, and the second sub-dam SDM2_3 may include or consist of the same material as that of the second planarization layer 180. The third sub-dam SDM3_3 may include or consist of the same material as that of the pixel-defining layer 190, and the fourth sub-dam SDM4_3 may include or consist of the same material as that of the spacer 191.

Since the width of the second sub-dam SDM2_3 is larger than that of the first sub-dam SDM1_3, the second sub-dam SDM2_3 may cover the side surfaces of the first sub-dam SDM1_3. The width of the fourth sub-dam SDM4_3 is larger than that of the first to third sub-dams SDM1_3, SDM2_3 and SDM3_3, so that the fourth sub-dam SDM4_3 may cover the side surfaces of the first to third sub-dams SDM1_3, SDM2_3 and SDM3_3. The widths of the first to fourth sub-dams SDM1_3, SDM2_3, SDM3_3 and SDM4_3 may be lengths defined in the first direction DR1 or the second direction DR2. It should be noted that the order in which the first to fourth sub-dams SDM1_3, SDM2_3, SDM3_3 and SDM4_3 of the third dam DM3 are stacked on one another is not limited thereto.

The first inorganic encapsulation layer TFE1 and the second inorganic encapsulation layer TFE3 may contact each other on a part of the side surface of the third dam DM3.

Since the third dam DM3 is desired to support the sealing member OS, the length of the third dam DM3 in the second direction DR2 may be similar to the length of the sealing member OS in the second direction DR2. That is to say, the length of the third dam DM3 in the second direction DR2 may be larger than the lengths of the first dam DM1 and the second dam DM2 in the second direction DR2.

The sealing member OS may include or consist of a material including or consisting of epoxy or acrylic. The sealing member OS may be cured by ultraviolet rays to seal the space between the first substrate SUB1 and the second substrate SUB2.

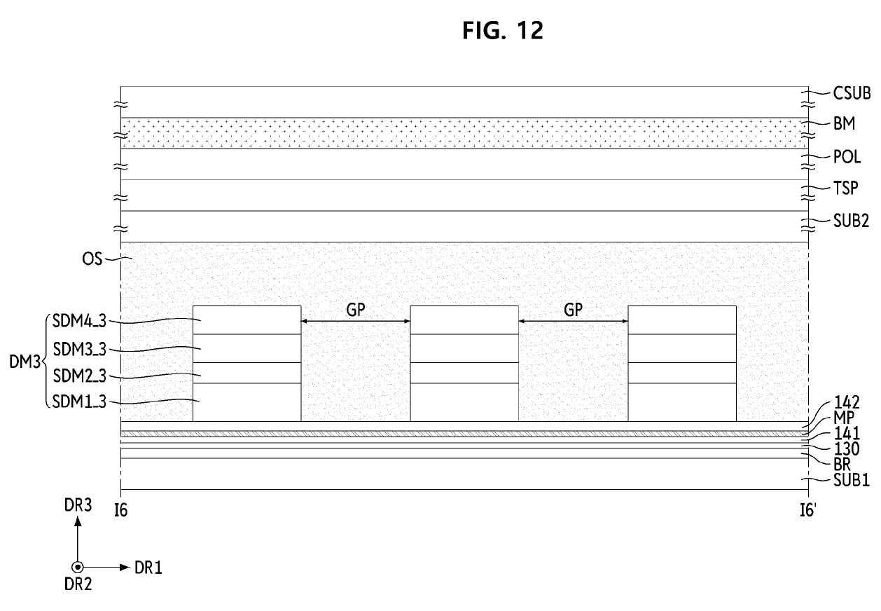

FIG. 12 is a cross-sectional view showing an embodiment of the display panel, taken along line I6 – I6' of FIG. 5. FIG. 12 shows a cross-section of the second dam area DMA2 on the upper side of the display panel 100. The following descriptions will focus on differences between the embodiment of FIGS. 10 and 11 and the embodiment of FIG. 12 and the redundant descriptions will be omitted.

Referring to FIG. 12, a plurality of third dams DM3 is arranged in parallel in the first direction DR1. There may be a gap GP between neighboring (adjacent) ones of the third dams DM3.

The length of the third dams DM3 in the first direction DR1 may be equal to or greater than the length of the gaps GP in the first direction DR1. When the length of the gaps GP in the first direction DR1 is too large, the filling member FL may overflow. On the contrary, when the length of the gaps GP in the first direction is too small, bubbles BUB (refer to FIG. 6) in the filling member FL may not be sufficiently released. Therefore, the length of the third dams DM3 in the first direction DR1 and the length of the gaps GP in the first direction DR1 may vary depending on the process.

The sealing member OS may be placed on a surface of the second substrate SUB2 and may overlap with the second dam area DMA2 in the third direction DR3. The sealing member OS may fill the space between the first substrate SUB1 and the second substrate SUB2 in the second dam area DMA2. Since the distance between the second inter-dielectric layer 142 and the surface of the second substrate SUB2 in the gap GP of the second dam area DMA2 is greater than the distance between the upper surface of the third dam DM3 and the surface of the second substrate SUB2, bubbles BUB (refer to FIG. 6) generated as the filling member FL fills between the first substrate SUB1 and the second substrate SUB2 while they are bonded together may be released to the outside through the gap GP.

Although the cross-section of the third dams DM3 is in a quadrangular shape, e.g., rectangular shape in FIG. 12, the cross-sectional shape of the third dams DM3 is not limited to this. In an embodiment, the cross-section of the third dams DM3 may be a trapezoidal shape, with the fourth sub-dam SDM4_3 surrounding the side surfaces of all of the first to third sub-dams SDM1_3, SDM2_3 and SDM3_3, depending on the way how the first to fourth sub-dams SDM1_3, SDM2_3, SDM3_3 and SDM4_3 are stacked on one another, for example.

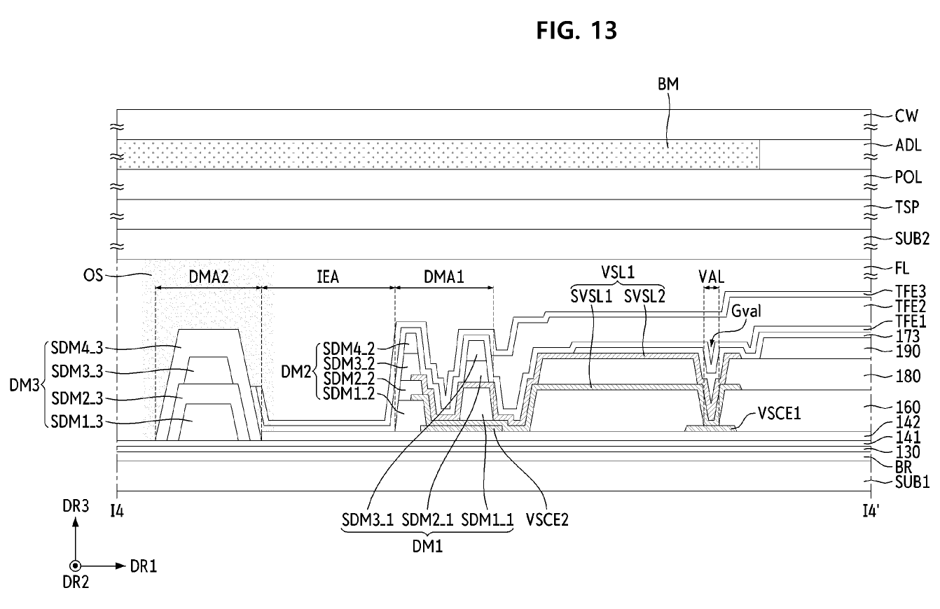

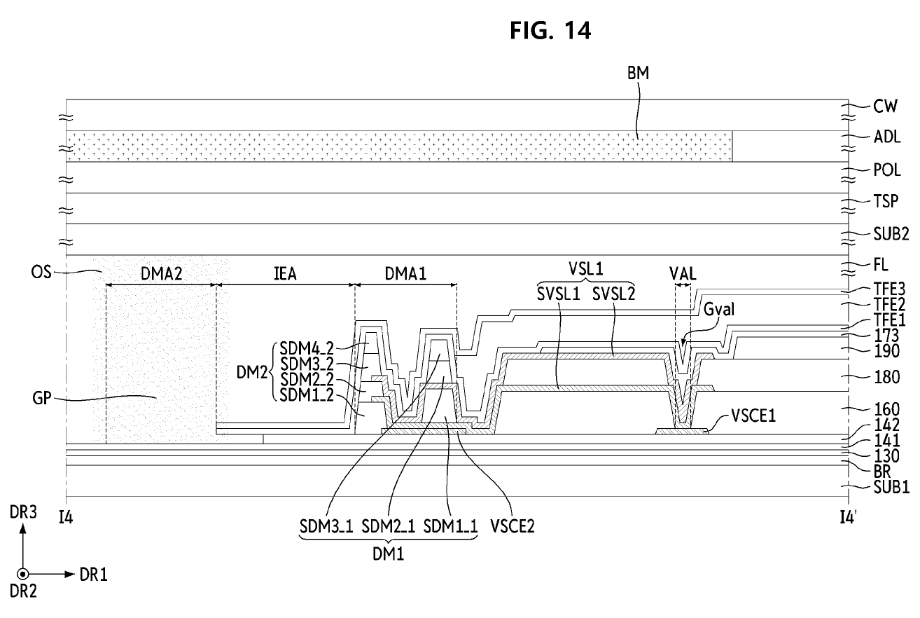

FIG. 13 is a cross-sectional view showing another embodiment of the display panel, taken along line I4 – I4' of FIG. 5. FIG. 14 is a cross-sectional view showing another embodiment of the display panel, taken along line I5 - I5' of FIG. 5.

The embodiment of FIGS. 13 and 14 is different from the embodiments of FIGS. 7 to 11 in that the metal pattern MP overlapping with the third dam DM3 in the third direction DR3 and the second inter-dielectric layer 142 are eliminated. The following descriptions will focus on differences between the embodiments of FIGS. 7 to 11 and the embodiment of FIGS. 13 and 14 and the redundant descriptions will be omitted.

Referring to FIGS. 13 and 14, the second inter-dielectric layer 142 may be disposed in the first dam area DMA1 but not in the second dam area DMA2. The first dam DM1 and the second dam DM2 in the first dam area DMA1 may be disposed on the second inter-dielectric layer 142, and the third dam DM3 of the second dam area DMA2 may be disposed on the first inter-dielectric layer 141.

In FIGS. 13 and 14, the metal patterns MP shown in FIGS. 8 to 11 may not be arranged. That is, there may be no metal patterns MP overlapping with the third dam DM3 in the third direction DR3.

To sum up, since the metal patterns MP overlapping with the third dam DM3 in the third direction DR3 and the second inter-dielectric layer 142 are eliminated, the length of the sealing member OS in the third direction DR3 may increase. Specifically, in FIGS. 13 and 14, the sealing member OS is disposed between the first inter-dielectric layer 141 and the surface of the second substrate SUB2, and thus the length of the sealing member OS may increase compared to the embodiment of FIGS. 8 and 9 where the sealing member OS is disposed between the second inter-dielectric layer 142 and the surface of the second substrate SUB2.

As the length of the sealing member OS increases, it may take more time for the sealing member OS to fill the space between the first substrate SUB1 and the second substrate SUB2 in the second dam area DMA2 during bonding the first substrate SUB1 and the second substrate SUB2 together. Therefore, during the bonding the first substrate SUB1 and the second substrate SUB2 together, the time taken for bubbles BUB generated by the filling material FL to escape through the gap GP may increase. As a result, the bubbles BUB may be more easily released to the outside.

The display device in the embodiment may be applied to a variety of electronic devices. An electronic device in an embodiment includes the display device described above, and may further include a module or device having additional features in addition to the display device.

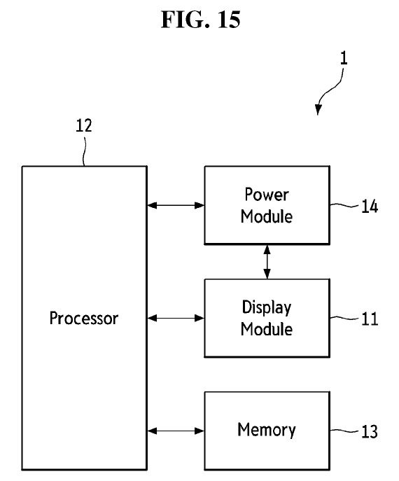

FIG. 15 is a block diagram of an embodiment of an electronic device of the disclosure. Referring to FIG. 15, an electronic device 1 in an embodiment of the disclosure may include a display module 11, a processor 12, a memory 13, and a power module 14.

The processor 12 may include at least one of: a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power desired for the operation of the electronic device 1.

At least one of the elements of the electronic device 1 described above may be included in the display devices in the embodiments described above. In addition, some of the individual modules functioning as a single module may be included in the display device while some others may be provided separately from the display device. In an embodiment, the display device may include the display module 11, and the processor 12, the memory 13 and the power module 14 may be implemented as other devices inside the electronic device 1 instead of the display device, for example.

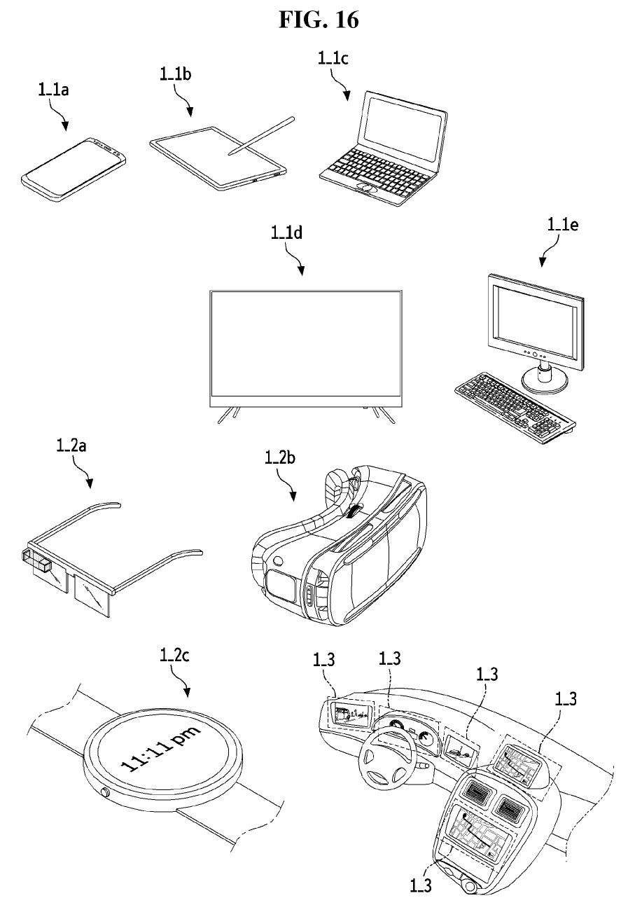

FIG. 16 is a view showing electronic devices according to a variety of embodiments of the disclosure.

Referring to FIG. 16, a variety of electronic devices employing display devices in embodiments may include not only image display electronic devices such as a smart phone 1_1a, a tablet PC 1_1b, a laptop computer 1_1c, a television (“TV”) 1_1d and a desktop monitor 1_1e, but also wearable electronic devices including display modules such as smart glasses 1_2a, a head-mounted display 1_2band a smart watch 1_2c, and electronic devices for vehicles 1_3 including display modules such as a center information display (“CID”) placed on the dashboard, the center fascia and the dashboard of a vehicle, and a room mirror display.

In an embodiment, the display device includes emission areas including light-emitting elements emitting lights in different wavelength bands from each other, respectively, an encapsulation layer on the light-emitting elements, a reflective polarizing member on the encapsulation layer and including a wire grid pattern which, among incident light from outside the display device, transmits light having an optical axis in a first direction and reflects light having an optical axis in a second direction orthogonal to the first direction, and an absorptive polarizing member which is on the reflective polarizing member and transmits the light having the optical axis in the first direction together with absorbing the light having the optical axis in the second direction. The wire grid pattern overlaps an emission area among the emission areas and non-overlaps remaining emission areas.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a first substrate;
a plurality of light-emitting elements arranged in a display area on the first substrate and outputting light;
a plurality of first area dams arranged in a non-display area next to the display area and spaced apart from one another;
a sealing member disposed in a space between the plurality of first area dams and over the plurality of first area dams; and
a filling member disposed over the plurality of light-emitting elements and surrounded by the sealing member.

2. The display device of claim 1, further comprising: a second substrate disposed on the filling member and the sealing member.

3. The display device of claim 1, wherein the plurality of first area dams is spaced apart from one another in a first direction, and
wherein a width of the sealing member in a second direction perpendicular to the first direction is larger than a width of the plurality of first area dams in the second direction.

4. The display device of claim 1, further comprising:
an encapsulation layer disposed between the plurality of light-emitting elements and the filling member,
wherein the encapsulation layer comprises:
a first inorganic encapsulation layer disposed over the plurality of light-emitting elements;
an organic encapsulation layer disposed on the first inorganic encapsulation layer; and
a second inorganic encapsulation layer disposed on the organic encapsulation layer.

5. The display device of claim 4, further comprising:
a plurality of second area dams arranged between the plurality of first area dams and the display area in the non-display area to prevent overflow of the organic encapsulation layer.

6. The display device of claim 4, wherein the first inorganic encapsulation layer and the second inorganic encapsulation layer overlap with the plurality of first area dams in a thickness direction of the first substrate.

7. The display device of claim 5, wherein the plurality of second area dams further comprises:
a first dam; and
a second dam placed between the first dam and the plurality of first area dams.

8. The display device of claim 7, wherein a height of the first dam is smaller than a height of a first area dam of the plurality of first area dams, and
wherein a height of the second dam is equal to the height of the first area dam.

9. The display device of claim 7, wherein a distance between the first dam and the second dam is smaller than a distance between the second dam and one of the plurality of first area dams which is closest to the second dam.

10. The display device of claim 7, further comprising:
an active layer disposed on the first substrate;
a gate insulator disposed on the active layer;
a first gate metal layer disposed on the gate insulator;
a first inter-dielectric layer disposed on the first gate metal layer;
a second gate metal layer disposed on the first inter-dielectric layer;
a second inter-dielectric layer disposed on the second gate metal layer;
a first data metal layer disposed on the second inter-dielectric layer;
a first planarization layer disposed on the first data metal layer;
a second data metal layer disposed on the first planarization layer; and
a second planarization layer disposed on the second data metal layer.

11. The display device of claim 10, wherein the plurality of first area dams overlaps with a first metal pattern comprising a material identical to a material of the second gate metal layer.

12. The display device of claim 11, wherein the plurality of first area dams contacts the second inter-dielectric layer.

13. The display device of claim 11, wherein the plurality of first area dams contacts the first inter-dielectric layer.

14. The display device of claim 10, wherein each of the plurality of first area dams comprises:
a first sub-dam comprising a material identical to a material of the first planarization layer; and
a second sub-dam comprising a material identical to a material of the second planarization layer.

15. The display device of claim 14, further comprising:
a first electrode of each of the plurality of light-emitting elements disposed on the second planarization layer;
an emissive layer of each of the plurality of light-emitting elements disposed on the first electrode;
a pixel-defining layer disposed on at least a part of the first electrode;
a second electrode of each of the plurality of light-emitting elements disposed on the first electrode and the pixel-defining layer; and
a spacer disposed on the pixel-defining layer.

16. The display device of claim 15, wherein each of the plurality of first area dams further comprises:
a third sub-dam comprising a same material as the pixel-defining layer; and
a fourth sub-dam comprising a same material as the spacer.

17. The display device of claim 16, wherein the first dam comprises:
a first sub-dam comprising a material identical to the material of the second planarization layer;
a second sub-dam comprising a material identical to the material of the pixel-defining layer; and
a third sub-dam comprising a material identical to the material of the spacer.

18. The display device of claim 17, wherein the second dam comprises:
a first sub-dam comprising a material identical to the material of the first planarization layer and the first sub-dam of each of the plurality of first area dams;
a second sub-dam comprising a material identical to the material of the second planarization layer and the second sub-dam of each of the plurality of first area dams;
a third sub-dam comprising a material identical to the material of the pixel-defining layer and the third sub-dam of each of the plurality of first area dams; and
a fourth sub-dam comprising a material identical to the material of the spacer and the fourth sub-dam of each of the plurality of first area dams.

19. An electronic device comprising:
a display module which displays an image, the display module comprising:
a first substrate;
a plurality of light-emitting elements arranged in a display area on the first substrate and outputting light;
a plurality of first area dams arranged in a non-display area next to the display area and spaced apart from one another;
a sealing member disposed in a space between the plurality of first area dams and over the plurality of first area dams; and
a filling member disposed over the plurality of light-emitting elements and surrounded by the sealing member; and
a processor for transmitting an image data signal to the display module.

20. The electronic device of claim 19, wherein the plurality of first area dams is spaced apart from one another in a first direction, and
wherein a width of the sealing member in a second direction perpendicular to the first direction is larger than a width of the plurality of first area dams in the second direction.
